(19) United States
(12) Patent Application Publication
(10) Pub. No.: US 2023/0050000 A1
(43) Pub. Date: Feb. 16, 2023

(54) INSPECTION SOCKET

(71) Applicant: YOKOWO CO., LTD., Kita-ku, Tokyo (JP)

(72) Inventors: Takayoshi OKUNO, Tomioka-shi, Gunma (JP); Kouji USUDA, Tomioka-shi, Gunma (JP)

(73) Assignee: YOKOWO CO., LTD., Kita-ku, Tokyo (JP)

(21) Appl. No.: 17/792,146

(22) PCT Filed: Dec. 16, 2020
(86) PCT No.: PCT/JP2020/046951

§ 371 Date: Jul. 12, 2022

(30) Foreign Application Priority Data
Jan. 30, 2020 (JP) 2020-013689

(51) Int. Cl. G01R 1/067; G01R 1/073

(52) U.S. Cl. CPC G01R 1/06722; G01R 1/07364

(57) ABSTRACT

An inspection socket includes: a pin block that is configured to support a contact probe in a manner of exposing a tip end of the contact probe from an exposed surface and inclining the contact probe in a predetermined direction relative to a direction perpendicular to the exposed surface; and a pressing portion that is configured to press an inspection target IC package that is to come into contact with the contact probe.

### TECHNICAL FIELD

The present invention relates to an inspection socket.

### BACKGROUND ART

Commonly, an inspection socket used for inspection of an IC package, such as a performance test, has been known. The inspection socket is used for electrically connecting an inspection target IC package to an inspection device, and includes a plurality of contact probes arrayed corresponding to an arrangement of electrode terminals of the inspection target IC package.

As an inspection socket of this type, a socket has also been known in which a contact probe is inclined so as to obliquely come into contact with an electrode terminal (see Patent Literature 1). In Patent Literature 1, in order to make an array of a plurality of contact probes symmetrical, inclination directions of the contact probes are reversed with a center of the array as a boundary. This is for the purpose that, when the contact probe is brought into contact with the electrode terminal, the inspection target IC package does not move in a direction parallel to the arrangement of the electrode terminal, and a scrubbing operation on a surface of the terminal is reliably performed. When the scrubbing operation is performed, even if an oxide film, dirt, or the like is present on the surface of the terminal, a tip end of the contact probe can be reliably brought into contact with the electrode terminal under the oxide film, dirt, or the like, and the conduction between the electrode terminal and the contact probe can be ensured.

### Citation List

### Patent Literature

Patent Document 1: U.S. Pat. No. 9766268

### SUMMARY OF INVENTION

### Technical Problem

However, in the configuration of Patent Literature 1, it is necessary to form support holes (stepped holes) of the contact probes on support portions for supporting the contact probes in a manner of being inclined in different directions. This leads to an increase in a size of the inspection socket and an increase in the complexity of processing of the support portion, resulting in an increase in cost. It may be difficult to array the contact probes symmetrically depending on the arrangement and the number of electrode terminals in the inspection target IC package.

An object of the present invention is to stably perform a scrubbing operation when a contact probe and an electrode terminal of an inspection target IC package are brought into contact with each other.

### Solution to Problem

According to an aspect of the present invention, there is provided an inspection socket including: a pin block that is configured to support a contact probe in a manner of exposing a tip end of the contact probe from an exposed surface and inclining the contact probe in a predetermined direction relative to a direction perpendicular to the exposed surface; and a pressing portion that is configured to press an inspection target IC package that is to come into contact with the contact probe.

According to this aspect, the pin block can support the contact probe in a manner of inclining the contact probe in the predetermined direction. In addition, the inspection target IC package can be pressed by the pressing portion. The pin block is inclined in the predetermined direction, and therefore, when the contact probe and the electrode terminal of the inspection target IC package are brought into contact with each other, the inspection target IC package is moved based on an inclination direction of the contact probe, and there is a possibility that the scrubbing operation hardly occurs. However, since the inspection target IC package is pressed by the pressing portion, such a situation can be suppressed, and the scrubbing operation can be stably performed when the contact probe and the electrode terminal of the inspection target IC package are brought into contact with each other. In addition, since the inclination directions of the contact probes may be the same, it is not necessary to increase the size of the pin block, and it is not necessary to perform complicated processing on the pin block for supporting the contact probes. Since the inspection target IC package is pressed by the pressing portion, a positioning accuracy of the inspection target IC package can be improved as compared with the case where the pressing portion is not provided.

### BRIEF DESCRIPTION OF DRAWINGS

FIG. 1 is an external view illustrating a configuration example of an inspection socket.

FIG. 2 is a top view illustrating a configuration example of a socket body.

FIG. 3 is a cross-sectional view taken along a line III-III in FIG. 2.

FIG. 4 is a diagram for illustrating a positional change of a pressing portion.

FIG. 5 is another diagram for illustrating the positional change of the pressing portion.

FIG. 6 is a top view illustrating a configuration example of a socket body according to a first modification.

FIG. 7 is a diagram for illustrating a positional change of a pressing portion according to the first modification.

FIG. 8 is a top view illustrating a configuration example of a socket body according to a second modification.

FIG. 9 is a diagram for illustrating a positional change of a pressing portion according to the second modification.

FIG. 10 is a diagram for illustrating a positional change of a pressing portion according to a third modification.

FIG. 11 is another diagram for illustrating the positional change of the pressing portion according to the third modification.

FIG. 12 is a top view illustrating a configuration example of a socket body according to a fourth modification.

FIG. 13 is a diagram for illustrating a positional change of a tapered member and a spring according to the fourth modification.

FIG. 14 is another diagram for illustrating the positional change of the tapered member and the spring according to the fourth modification.

FIG. 15 is a schematic view illustrating a relation between an inclination direction of a contact probe and a direction in which an inspection target IC package is pressed.

### DESCRIPTION OF EMBODIMENTS

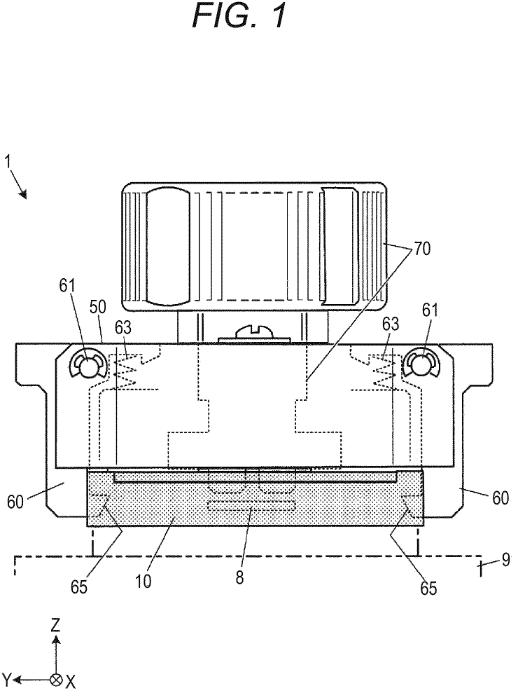

Hereinafter, examples of preferred embodiments of the present invention will be described. However, a mode to which the present invention can be applied is not limited to the following embodiments. In the description of the present embodiment, an up-down direction of the inspection socket 1 is defined such that a direction in which a lid body 50 is closed is the downward direction and a direction in which the lid body 50 is opened is the upward direction. An inspection socket 1 is used with the downward direction facing a vertically downward direction due to gravity. Therefore, when an inspection target IC package 8 is placed in the inspection socket 1, the IC package 8 is in a state of being placed on package support portions 20 in the inspection socket 1 by its own weight, as will be described later. In each of the drawings, the up-down direction is defined as a Z-axi s direction, and three orthogonal axes of a right-handed system, which define an X-axis direction and a Y-axis direction perpendicular to the Z-axis direction in common, are defined as common directions. A Z-axis positive direction is the upward direction, and a Z-axis negative direction is the downward direction. A direction from the front to the back toward a paper surface of FIG. 1 is an X-axis positive direction, and a direction from the back to the front is an X-axis negative direction. A direction from the right to the left in a left-right direction of FIG. 1 orthogonal to the X-axis direction and the Z-axis direction is a Y-axis positive direction, and a direction from the left to the right is a Y-axis negative direction.

FIG. 1 is an external view illustrating a configuration example of the inspection socket 1 according to the present embodiment. As illustrated in FIG. 1, the inspection socket 1 includes a socket body 10, the lid body 50, and a pressure applying mechanism 70 as a pressing member.

The socket body 10 allows the inspection target IC package 8 to be taken in and out, and is attached to the inspection device 9. The lid body 50 supports the pressure applying mechanism 70 above the socket body 10. The pressure applying mechanism 70 is used for pressing the inspection target IC package 8 in the socket body 10 below the pressure applying mechanism 70 from above, and applies a load to the inspection target IC package 8.

The lid body 50 is provided with a pair of hooks 60. In the example of FIG. 1, the hooks 60 are provided on both left and right sides, respectively. Each of the hooks 60 is swingably supported by a hook swing shaft 61 along the X-axis direction. Regarding the hooks 60, the hook 60 on the right side of FIG. 1 is biased by a spring 63 at a hook swing shaft 61 in a clockwise direction when viewed from the X-axis negative direction, and the hook 60 on the left side of FIG. 1 is biased by a spring 63 at a hook swing shaft 61 in a counterclockwise direction when viewed from the X-axis negative direction.

The hooks 60 maintain a state in which the lid body 50 covers the socket body 10 from above by the engagement of engagement claws 65 with the socket body 10. When the hooks 60 are removed by releasing a biasing state generated by the springs 63 and the lid body 50 is removed from the socket body 10, an inside of the socket body 10 is exposed and the inspection target IC package 8 can be taken in and out.

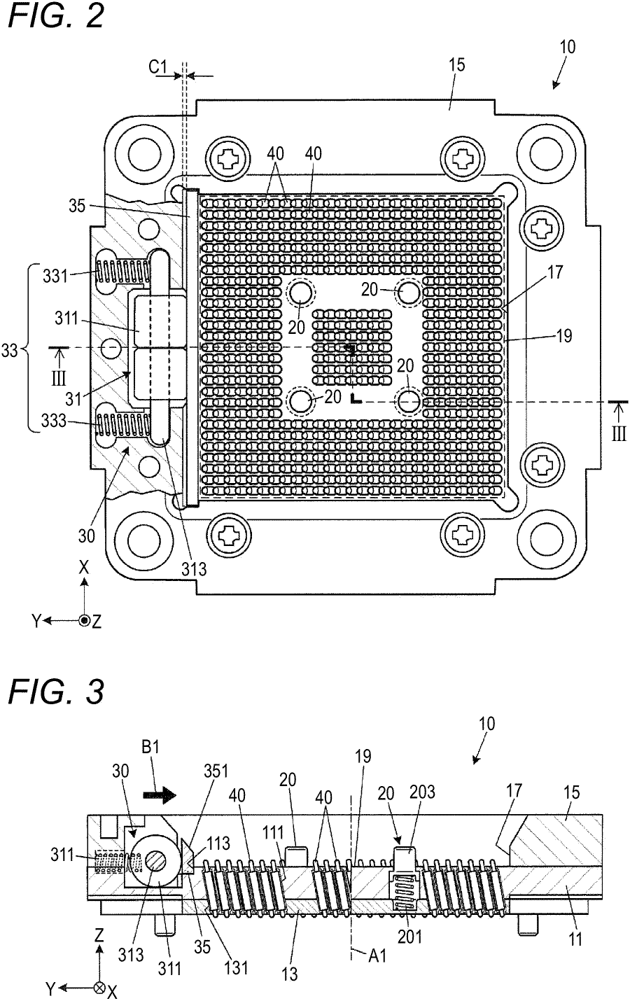

FIG. 2 is a top view illustrating a configuration example of the socket body 10. FIG. 3 is a cross-sectional view taken along a line III-III in FIG. 2. In FIG. 2, a part (left side portion in FIG. 2) of a guide member 15 is cut out to show a structure of a pressing portion 30 inside.

As illustrated in FIGS. 2 and 3, the socket body 10 includes a pin block 11, a pin plate 13 attached to a lower surface of the pin block 11, a frame-shaped guide member 15, the pressing portion 30, and a tapered member 35 as an interposed portion. The guide member 15 is placed on an outer peripheral portion of the pin block 11 on an upper surface of the pin block 11. The tapered member 35 is disposed inside a side portion (a left side portion in FIG. 2 and the like) of the guide member 15 on an inclination direction side (a Y-axis positive direction) to be described later. The pin block 11, the guide member 15, and the tapered member 35 form an accommodation recess 17 for accommodating the inspection target IC package 8 (not illustrated in FIGS. 2 and 3). The inspection target IC package 8 placed in the accommodation recess 17 is accommodated in a predetermined position of the accommodation recess 17 by being pressed down from above by the pressure applying mechanism 70. The pressing portion 30 is used for pressing the inspection target IC package 8 accommodated in the accommodation recess 17 in a pressing direction B1. The pressing direction B1 is a direction parallel to the Y-axis negative direction. The tapered member 35 is interposed between a pressing member 31 and the inspection target IC package 8 when the inspection target IC package 8 is accommodated in the accommodation recess 17.

A bottom surface of the accommodation recess 17 is a central portion of the upper surface of the pin block 11 and is a portion surrounded by the guide member 15. Side walls of the accommodation recess 17 are formed by the guide member 15 and the tapered member 35. Among the side walls of the accommodation recess 17, three side walls formed by the guide member 15 are fixed, and one side wall formed by the tapered member 35 is movable along the Y-axis direction.

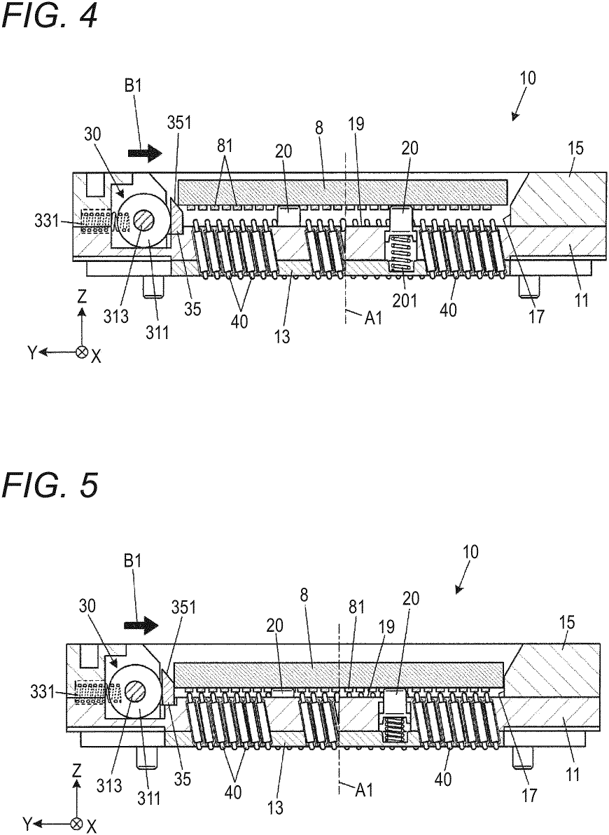

The pin block 11 supports contact probes 40 on the bottom surface of the accommodation recess 17. The contact probes 40 are used for electrically connecting electrode terminals 81 of the inspection target IC package 8 shown in FIG. 4 and the like to the inspection device 9. The electrode terminals 81 each are made of gold, and may be made of solder. The contact probes 40 each include a conductive tube, a terminal-side plunger and a board-side plunger respectively provided at both ends of the conductive tube and a spring provided in the tube. The spring in the tube biases the terminal-side plunger and the board-side plunger in directions away from each other, and the terminal-side plunger and the board-side plunger protrude from both ends of the tube, respectively.

Returning to the description of the pin block 11, in the present embodiment, the pin block 11 supports the plurality of contact probes 40 arrayed along an XY plane so as to correspond to an arrangement of the electrode terminals 81 in the inspection target IC package 8. In the pin block 11, the upper surface corresponding to the bottom surface of the accommodation recess 17 is used as an exposed surface 19, and upper tip ends (terminal-side plungers) of the contact probes 40 are exposed from the exposed surface 19. The pin block 11 is made of metal. The pin block 11 may be made of an insulating resin.

More specifically, as illustrated in FIG. 3, the pin block 11 includes, in a central portion thereof, a plurality of block-side through holes 111 inclined in a predetermined direction with respect to a vertical direction of the exposed surface 19 (a direction parallel to a central axis A1 of the socket body 10 illustrated by a dash-dotted line in FIG. 3, the Z-axis direction). The block-side through holes 111 each are a stepped hole having a narrow opening on an upper side (the exposed surface 19 side) in order to suppress the contact probes 40 from coming off. Then, the contact probes 40 are inserted into the respective block-side through holes 111, so that the contact probes 40 are supported in a posture in which the contact probes 40 are inclined in the above-described predetermined directions (hereinafter, also referred to as an “inclination direction”). The inclination directions of the contact probes 40 are the same. When the pin block 11 is made of metal, a resin member interposed between the pin block 11 and the contact probe 40 is disposed in a vicinity of an opening portion on the upper side (exposed surface 19 side) of the block-side through hole 111. With this resin member, the pin block 11 and the contact probe 40 can be brought into a non-contact state.

The pin block 11 includes a plurality of package support portions 20. In the present embodiment, four package support portions 20 are arranged at a central portion of the pin block 11 so as to avoid the array of the contact probes 40. However, the arrangement positions of the package support portions 20 are not limited to the central portion.

The package support portions 20 each include a spring 201 installed inside the pin block 11, and a spring cap 203 that covers an upper portion of the spring 201 and is biased upward by the spring 201. The pin block 11 is set to a height at which a head portion of the spring cap 203 (an upper end portion of the spring cap 203) protrudes from the exposed surface 19. Specifically, as illustrated in FIG. 3, a height of the upper end portion of the spring cap 203 is defined to be a height exceeding the tip end of each of the contact probes 40 exposed from the exposed surface 19. The inspection target IC package 8 inserted into the socket body 10 can be held above the contact probes 40 in a state of being not in contact with the terminal-side plunger (see FIG. 4).

The pin plate 13 includes a plurality of plate-side through holes 131 inclined in the inclination direction at the same inclination angle as the block-side through holes 111 of the pin block 11. Each of the plate-side through holes 131 is a stepped hole having a narrow opening on a lower side in order to suppress the contact probes 40 from coming off. Each of the plate-side through holes 131 corresponds to each of the block-side through holes 111, and is formed at a position communicating with the corresponding block-side through hole 111. The contact probes 40 inserted into the block-side through holes 111 penetrate the pin plate 13 through the plate-side through holes 131, and a lower tip end (board-side plunger) of each of the contact probes 40 is held in a manner of being exposed to the inspection device 9 side. The pin plate 13 is made of an insulating resin.

A part of an upper surface of the guide member 15 is a tapered surface inclined toward the accommodation recess 17 side. Since the guide member 15 has the tapered surface, the inspection target IC package 8 can be easily taken in and out of the socket body 10. An inclination angle of a tapered surface of the guide member 15 can be set as appropriate, and is preferably set to be the same as that of a tapered surface 351 of the tapered member 35. Accordingly, the accommodation recess 17 is surrounded by the inclined surfaces having the same inclination angle, and the inspection target IC package 8 is more easily taken in and out of the socket body 10.

The pressing portion 30 is used for pressing the inspection target IC package 8 accommodated in the accommodation recess 17. The pressing portion 30 presses the inspection target IC package 8 from a lateral side of the accommodation recess 17 in a predetermined pressing direction including a direction component opposite to the inclination direction of the contact probe 40.

The contact probe 40 is inclined in the Y-axis positive direction (counterclockwise when viewed from the X-axis negative direction) relative to the central axis A1 of the socket body 10 in a top view. That is, the contact probe 40 is inclined toward the Y-axis negative direction as it goes toward the Z-axis negative direction. There are a plurality of contact probes 40, all of which are inclined in the same direction. A Y-axis negative direction opposite to the inclination direction is defined as the pressing direction B1. Therefore, the pressing portion 30 is installed as a mechanism for pressing the inspection target IC package 8 accommodated in the accommodation recess 17 in the Y-axis negative direction that is the pressing direction B1.

The pressing portion 30 includes the pressing member 31 and an elastic member 33 that biases the pressing member 31 in the pressing direction B1. When the inspection target IC package 8 is accommodated in the accommodation recess 17, the pressing member 31 is moved, so that the elastic member 33 elastically deforms, and the pressing portion 30 presses the inspection target IC package 8 in the pressing direction B1 by an elastic force of the elastic deformation. The pressing portion 30 presses the inspection target IC package 8 in the pressing direction B1 via the tapered member 35.

The pressing member 31 includes a roller portion 311 and a support shaft 313 that rotatably supports the roller portion 311. The elastic member 33 includes a pair of springs 331 and 333, which are provided between both end portions of the support shaft 313 and an inner wall portion of an installation space. Then, a circumferential surface of the roller portion 311 comes into contact with the tapered member 35.

The tapered member 35 is a plate body disposed inside the guide member 15 along a side portion of the guide member 15 on the inclination direction side. The entire upper surface of the tapered member 35 is formed as a tapered surface 351 that is lowered toward a central portion of the accommodation recess 17. It is sufficient to include a tapered surface inclined toward the accommodation recess 17 side, and a part of the upper surface may be formed as a tapered surface. A length in a longitudinal direction (a length along the X-axis direction) of the tapered member 35 may be a length exceeding a length along the X-axis direction of the corresponding accommodation recess 17. On the other hand, a groove portion 113 is formed on the upper surface of the pin block 11 in accordance with a dimension of the tapered member 35. A length in the Y-axis direction of the groove portion 113 is larger than a length in the Y-axis direction of the tapered member 35 by a movable range C1 in which the tapered member 35 is pressed and moved by the roller portion 311. The tapered member 35 is fitted into the groove portion 113 and is disposed so as to be movable in the Y-axis direction. The tapered member 35 includes a detachment suppressing mechanism (not illustrated) for suppressing the tapered member 35 from being detached from the groove portion 113 when the inspection target IC package 8 is attached or detached.

Therefore, when the inspection target IC package 8 is not accommodated in the accommodation recess 17, the tapered member 35 is pressed by the roller portion 311 via a biasing force of the springs 331 and 333 in the pressing direction B1 on the support shaft 313, and a lower end of the tapered member 35 comes into contact with a step of the groove portion 113. This state is a standard state. FIGS. 2 and 3 illustrate a standard state of the pressing portion 30 and the tapered member 35, and illustrate a state where the inspection target IC package 8 is not accommodated in the accommodation recess 17. On the other hand, the tapered member 35 is allowed to move along the Y-axis direction between a position where the tapered member 35 abuts against the step in the standard state and a position where the tapered member 35 is retracted from the position by the movable range C1. Therefore, when the inspection target IC package 8 is inserted into the socket body 10 and pressed down from above, the tapered member 35 moves in the Y-axis positive direction (the direction opposite to the pressing direction B1) and the inspection target IC package 8 is accommodated in the accommodation recess 17. The inspection target IC package 8 is in a state of being pressed in the pressing direction B1 from the lateral side of the inclination direction side.

FIGS. 4 and 5 are diagrams for illustrating positional changes of the pressing portion 30 and the tapered member 35 when the inspection target IC package 8 is accommodated in the accommodating recess 17. FIG. 4 shows a cross section taken along a line III-III in FIG. 2 when the inspection target IC package 8 is inserted into the socket body 10. FIG. 5 shows a cross section taken along the line III-III in FIG. 2 when the inspection target IC package 8 is pressed down from above and accommodated in the accommodation recess 17.

As illustrated in FIG. 4, when the inspection target IC package 8 is placed in the socket body 10, the inspection target IC package 8 is guided to an upper side of the accommodation recess 17 by the tapered surface of the guide member 15 and the tapered surface 351 of the tapered member 35, and is in a state of being elastically supported by the package support portions 20. In this state, the tapered member 35 is pressed by the roller portion 311 via the biasing force of the springs 331 and 333 in the pressing direction B1, and is pressed against the step of the groove portion 113.

Thereafter, when the pressure applying mechanism 70 applies a load to the inspection target IC package 8, as illustrated in FIG. 5, the inspection target IC package 8 is pressed down, and the spring 201 is contracted to lower support positions of the package support portions 20. Then, the tapered member 35 comes into contact with a side end of the inspection target IC package 8, and the tapered member 35 is pressed so as to retract in the Y-axis positive direction. The roller portion 311 pressed by the tapered member 35 that retracts moves so as to retract in the Y-axis positive direction, and the springs 331 and 333 contract. The inspection target IC package 8 receives an elastic force of the springs 331 and 333 in the Y-axis negative direction via the tapered member 35, and is in a state of being pressed in the pressing direction B1 by the pressing portion 30. An end surface (a side surface on a side in the Y-axis negative direction; a right side surface in FIGS. 4 and 5) of the inspection target IC package 8 on a side opposite to a side pressed by the pressing portion 30 is in a state of being in contact with the guide member 15. Therefore, the position of the inspection target IC package 8 in the left-right direction (XY plane) is in a fixed state, and thereafter, the inspection target IC package 8 only changes in position in the Z-axis negative direction.

When the inspection target IC package 8 is further pressed down, the tip end (terminal-side plunger) of each contact probe 40 exposed from the exposed surface 19 starts to come into contact with the corresponding electrode terminal 81. The contact probes 40 can extend and contract in an axial direction (longitudinal direction). Therefore, when the inspection target IC package 8 is pressed down and the electrode terminals 81 are pressed against the contact probes 40, the contact probes 40 in contact therewith start to contract. However, each of the contact probes 40 is disposed so as to be inclined relative to a direction (Z-axis direction) perpendicular to the exposed surface 19. The position of the inspection target IC package 8 in the left-right direction (XY plane) is in a fixed state. Therefore, the contact position where a tip end of the contact probe 40 is in contact with the electrode terminal 81 of the inspection target IC package 8 gradually changes in accordance with the descent of the inspection target IC package 8 (a positional change in the Z-axis negative direction), and the scrubbing operation on a surface of the terminal is performed.

As described above, according to the inspection socket 1 of the present embodiment, the plurality of contact probes 40 can be supported in a manner of being inclined in the predetermined inclination direction. The pressing portion 30 presses the inspection target IC package 8 accommodated in the accommodation recess 17 in a pressing direction B1 including a direction component opposite to the inclination direction of the contact probes 40. In the present embodiment, the inclination direction is a direction inclined in the Y-axis positive direction relative to the direction (Z-axis direction) perpendicular to the exposed surface 19, and the pressing direction B1 is the Y-axis negative direction that is a direction component opposite to the inclination direction. The inclination directions of all the contact probes 40 are the same, so that, when the inspection target IC package 8 is pressed against the contact probes 40, a force for moving the inspection target IC package 8 in a direction along the inclination direction (the Y-axis positive direction in the present embodiment) is applied to the inspection target IC package 8, and the IC package 8 may move in the Y-axis positive direction. However, since a pressing force is applied to the inspection target IC package 8 from the pressing direction B1 including the direction component opposite to the inclination direction, the movement in the Y-axis positive direction is suppressed. As a result, the contact position where the tip end of the contact probe 40 is in contact with the electrode terminal 81 of the inspection target IC package 8 gradually changes in accordance with the movement of the inspection target IC package 8 in the pressing direction (positional change in the Z-axis negative direction).

Therefore, when the contact probe 40 is pressed against the electrode terminal 81, the inspection target IC package 8 can be suppressed from moving in a direction other than the pressing direction (the Z-axis negative direction in the present embodiment), and a stable scrubbing operation can be performed.

It should be noted that modes to which the present invention can be applied are not limited to the above-described embodiment, and components can be appropriately added, omitted, or changed.

### First Modification

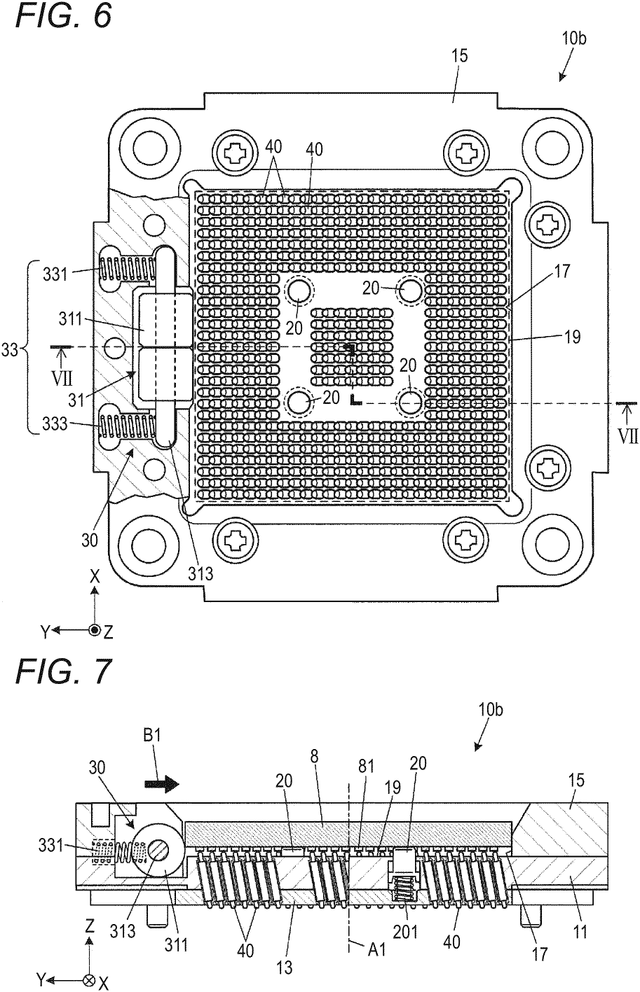

For example, the configuration in which the inspection target IC package 8 accommodated in the accommodation recess is pressed via the tapered member 35 has been described in the above-described embodiment. Alternatively, the pressing portion 30 may directly press the inspection target IC package 8. FIG. 6 is a diagram illustrating a configuration example of a socket body 10b according to a first modification. FIG. 7 is a cross-sectional view taken along a line VII-VII in FIG. 6, and shows a state where the inspection target IC package 8 is pressed down from above and accommodated in the accommodation recess 17. In FIGS. 6 and 7, the same components as those of the above-described embodiment are denoted by the same reference numerals.

As illustrated in FIGS. 6 and 7, the socket body 10b according to the first modification includes the pin block 11, the pin plate 13, the guide member 15, and the pressing portion 30. The configuration of the pressing portion 30 is the same as that of the above-described embodiment, and the roller portion 311 is biased in the pressing direction B1 by the springs 331 and 333 via the support shaft 313. The socket body 10b does not include the tapered member 35 according to the above-described embodiment.

When the inspection target IC package 8 is placed in the socket body 10b and the pressure applying mechanism 70 applies a load to the inspection target IC package 8, the inspection target IC package 8 is pressed down, and the spring 201 is contracted to lower the support position of the package support portions 20. Then, the roller portion 311 abuts against a side end of the inspection target IC package 8 and is pressed so as to retract in the Y-axis positive direction, and the springs 331 and 333 contract. The inspection target IC package 8 receives an elastic force of the springs 331 and 333 in the Y-axis negative direction via the roller portion 311, and is in a state of being pressed in the pressing direction B1 by the pressing portion 30. An end surface (a side surface on a side in the Y-axis negative direction; a right side surface in FIGS. 6 and 7) of the inspection target IC package 8 on a side opposite to a side pressed by the pressing portion 30 is in a state of being in contact with the guide member 15. Therefore, the position of the inspection target IC package 8 in the left-right direction (XY plane) is in a fixed state, and thereafter, the inspection target IC package 8 only changes in position in the Z-axis negative direction.

When the inspection target IC package 8 is further pressed down, the tip end (terminal-side plunger) of each contact probe 40 exposed from the exposed surface 19 starts to come into contact with the corresponding electrode terminal 81. The contact probes 40 can extend and contract in an axial direction (longitudinal direction). Therefore, when the inspection target IC package 8 is pressed down and the electrode terminals 81 are pressed against the contact probes 40, the contact probes 40 in contact therewith start to contract. However, each of the contact probes 40 is disposed so as to be inclined relative to a direction (Z-axis direction) perpendicular to the exposed surface 19. The position of the inspection target IC package 8 in the left-right direction (XY plane) is in a fixed state. Therefore, the contact position where a tip end of the contact probe 40 is in contact with the electrode terminal 81 of the inspection target IC package 8 gradually changes in accordance with the descent of the inspection target IC package 8 (a positional change in the Z-axis negative direction), and the scrubbing operation on a surface of the terminal is performed.

Also in the first modification, the same effects as those of the above-described embodiment can be achieved.

### Second Modification

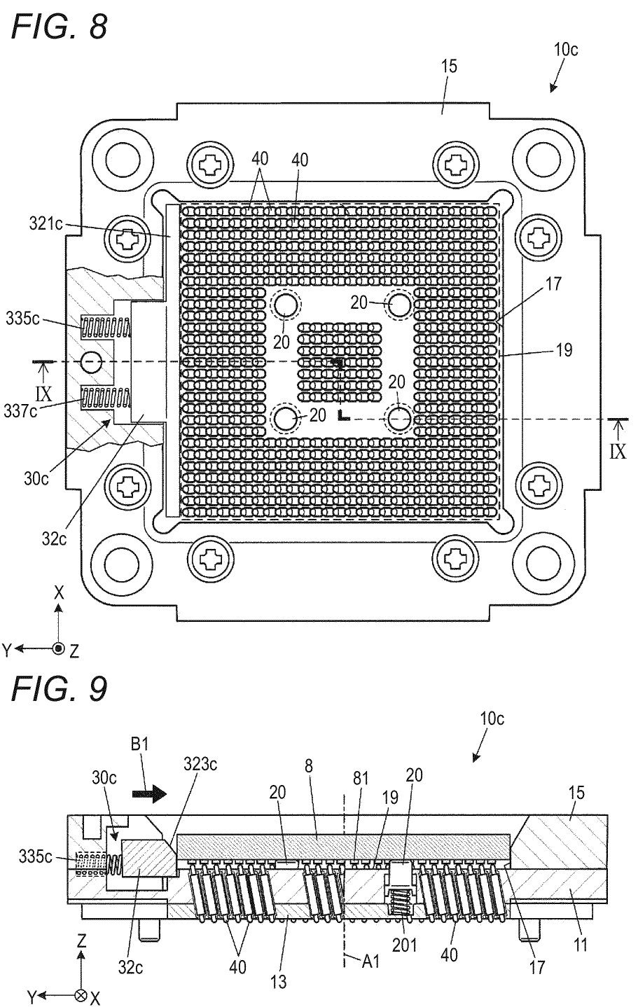

Further, the configuration example of the pressing portion 30 including the pressing member 31 that includes the roller portion 311 and the support shaft 313 has been described in the above-described embodiment, but the configuration of the pressing portion is not limited thereto. FIG. 8 is a diagram illustrating a configuration example of a socket body 10c in a second modification. FIG. 9 is a cross-sectional view taken along a line IX-IX in FIG. 8, and shows a state where the inspection target IC package 8 is pressed down from above and accommodated in the accommodation recess 17. In FIGS. 8 and 9, the same components as those of the above-described embodiment are denoted by the same reference numerals.

As illustrated in FIGS. 8 and 9, the socket body 10c according to the second modification includes the pin block 11, the pin plate 13, the guide member 15, and a pressing portion 30c. The pressing portion 30c includes a tapered member 32c as a pressing member instead of the roller portion 311 in the first modification. The pressing portion 30c includes a pair of springs 335c and 337c provided between the tapered member 32c and an inner wall portion of an installation space of the tapered member 32c as elastic members that bias the tapered member 32c in the pressing direction B1.

The tapered member 32c includes a plate-shaped portion 321c that is long along the X-axis direction as a whole. A central portion of the plate-shaped portion 321c in the longitudinal direction has a wide shape. The plate-shaped portion 321c forms a part of a side wall of the accommodation recess 17. In the tapered member 32c, a part of an upper surface of the plate-shaped portion 321c is formed as a tapered surface 323c that is lowered toward the central portion of the accommodation recess 17. It should be noted that the entire upper surface may be formed as a tapered surface.

When the inspection target IC package 8 is placed in the socket body 10c and the pressure applying mechanism 70 applies a load to the inspection target IC package 8, the inspection target IC package 8 is pressed down, and the spring 201 is contracted to lower the support position of the package support portions 20. Then, the plate-shaped portion 321c of the tapered member 32c abuts against the side end of the inspection target IC package 8 and is pressed so as to retract in the Y-axis positive direction, and the springs 335c and 337c are contracted by the retracting tapered member 32c. The inspection target IC package 8 receives an elastic force of the springs 335c and 337c in the Y-axis negative direction, and is in a state of being pressed in the pressing direction B1 by the pressing portion 30c. An end surface (a side surface on a side in the Y-axis negative direction; a right side surface in FIGS. 8 and 9) of the inspection target IC package 8 on a side opposite to a side pressed by the pressing portion 30c is in a state of being in contact with the guide member 15. Therefore, the position of the inspection target IC package 8 in the left-right direction (XY plane) is in a fixed state, and thereafter, the inspection target IC package 8 only changes in position in the Z-axis negative direction.

When the inspection target IC package 8 is further pressed down, the tip end (terminal-side plunger) of each contact probe 40 exposed from the exposed surface 19 starts to come into contact with the corresponding electrode terminal 81. The contact probes 40 can extend and contract in an axial direction (longitudinal direction). Therefore, when the inspection target IC package 8 is pressed down and the electrode terminals 81 are pressed against the contact probes 40, the contact probes 40 in contact therewith start to contract. However, each of the contact probes 40 is disposed so as to be inclined relative to a direction (Z-axis direction) perpendicular to the exposed surface 19. The position of the inspection target IC package 8 in the left-right direction (XY plane) is in a fixed state. Therefore, the contact position where a tip end of the contact probe 40 is in contact with the electrode terminal 81 of the inspection target IC package 8 gradually changes in accordance with the descent of the inspection target IC package 8 (a positional change in the Z-axis negative direction), and the scrubbing operation on a surface of the terminal is performed.

Also in the second modification, the same effects as those of the above-described embodiment can be achieved.

### Third Modification

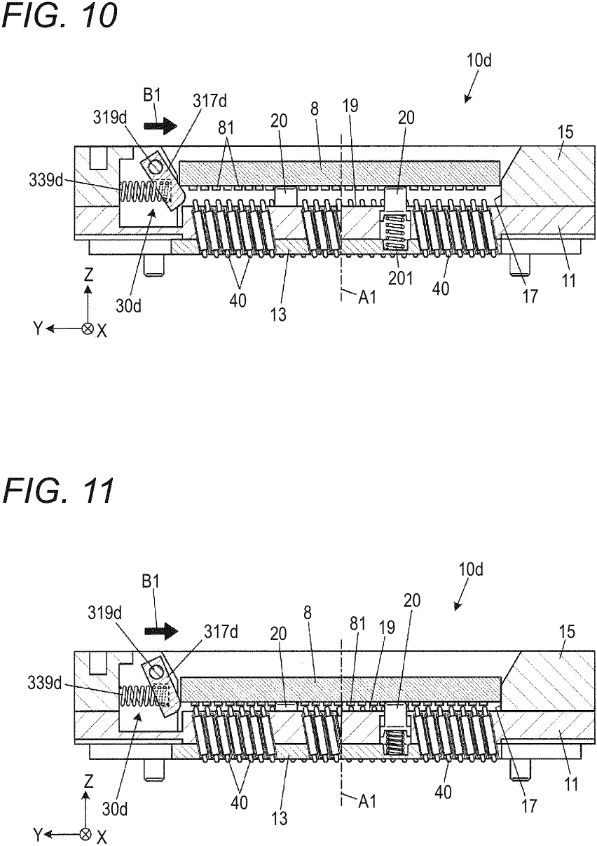

A configuration of the pressing portion may be another configuration. FIGS. 10 and 11 are longitudinal sectional views illustrating a configuration example of a socket body 10d according to a third modification, and illustrate a change in a pressing portion 30d when the inspection target IC package 8 is accommodated in the accommodation recess 17. Specifically, FIG. 10 illustrates a state where the inspection target IC package 8 is inserted into the socket body 10d. FIG. 11 illustrates a state where the inspection target IC package 8 is pressed down from above and accommodated in the accommodation recess 17. In FIGS. 10 and 11, the same components as those of the above-described embodiment are denoted by the same reference numeral s.

As illustrated in FIGS. 10 and 11, the socket body 10d according to the third modification includes the pin block 11, the pin plate 13, the guide member 15, and the pressing portion 30d. The pressing portion 30d includes, as a pressing member, a swing body 317d swingably supported by a swing shaft 319d along the X-axis direction. The pressing portion 30d includes a spring 339d as an elastic member that biases the swing body 317d in the pressing direction B1.

The spring 339d is disposed in a movable space of the swing body 317d provided in a side wall of the accommodation recess 17 in a posture in which the spring 339d biases the swing body 317d in the pressing direction B1. In a natural state where the inspection target IC package 8 is not placed, the swing body 317d is disposed in a posture in which the swing body 317d is inclined at the same angle as the tapered surface of the guide member 15.

When the inspection target IC package 8 is placed in the socket body 10d, the inspection target IC package 8 is guided to an upper side of the accommodation recess 17 by the tapered surface of the guide member 15 and the inclined surface of the swing body 317d, and is in a state of being elastically supported by the package support portions 20 (the state in FIG. 10).

Thereafter, when the pressure applying mechanism 70 applies a load to the inspection target IC package 8, the inspection target IC package 8 is pressed down, and the spring 201 is contracted to lower support positions of the package support portions 20. Then, the swing body 317d abuts against a side end of the inspection target IC package 8, and rotates around the swing shaft 319d in the clockwise direction when viewed from the X-axis negative direction, thereby contracting the spring 339d. The inspection target IC package 8 receives an elastic force of the contracted spring 339d in the Y-axis negative direction, and is in a state of being pressed in the pressing direction B1 by the pressing portion 30d. An end surface (a side surface on a side in the Y-axis negative direction; a right side surface in FIGS. 10 and 11) of the inspection target IC package 8 on a side opposite to a side pressed by the pressing portion 30d is in a state of being in contact with the guide member 15. Therefore, the position of the inspection target IC package 8 in the left-right direction (XY plane) is in a fixed state, and thereafter, the inspection target IC package 8 only changes in position in the Z-axis negative direction.

When the inspection target IC package 8 is further pressed down, the tip end (terminal-side plunger) of each contact probe 40 exposed from the exposed surface 19 starts to come into contact with the corresponding electrode terminal 81. The contact probes 40 can extend and contract in an axial direction (longitudinal direction). Therefore, when the inspection target IC package 8 is pressed down and the electrode terminals 81 are pressed against the contact probes 40, the contact probes 40 in contact therewith start to contract. However, each of the contact probes 40 is disposed so as to be inclined relative to a direction (Z-axis direction) perpendicular to the exposed surface 19. The position of the inspection target IC package 8 in the left-right direction (XY plane) is in a fixed state. Therefore, the contact position where a tip end of the contact probe 40 is in contact with the electrode terminal 81 of the inspection target IC package 8 gradually changes in accordance with the descent of the inspection target IC package 8 (a positional change in the Z-axis negative direction), and the scrubbing operation on a surface of the terminal is performed.

Also in the third modification, the same effects as those of the above-described embodiment can be achieved.

### Fourth Modification

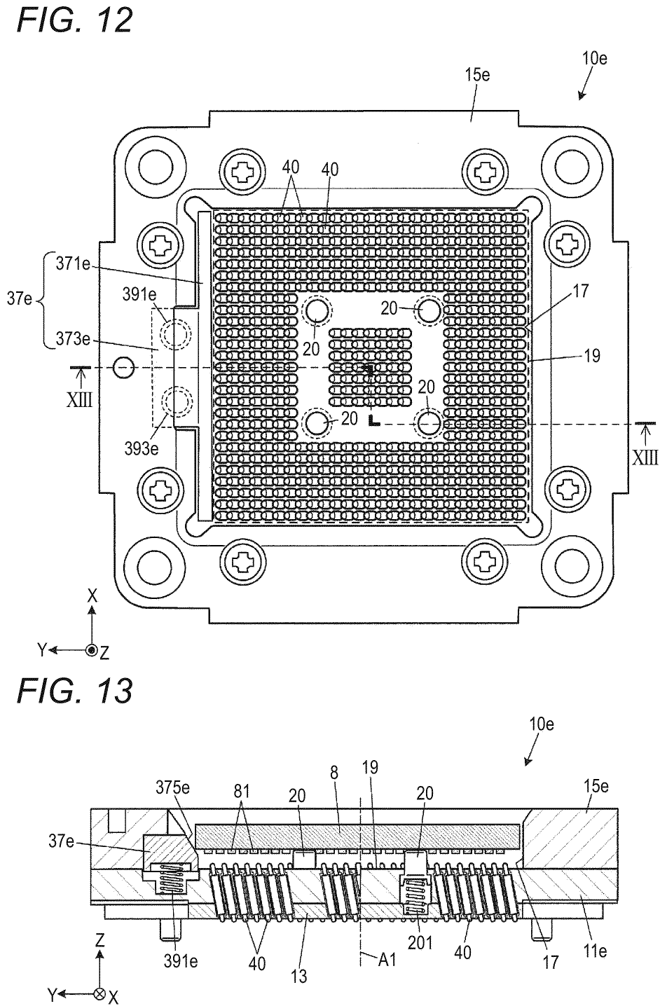

With a configuration different from the pressing portions 30, 30c, and 30d as shown in the embodiment and the first to third modifications, the inspection target IC package can also be suppressed from moving in the inclination direction when the contact probe and the electrode terminal are brought into contact with each other. FIG. 12 is a diagram illustrating a configuration example of a socket body 10e according to a fourth modification. FIGS. 13 and 14 are cross-sectional views taken along a line XIII-XIII in FIG. 12. FIG. 13 illustrates a state where the inspection target IC package 8 is inserted into the socket body 10e. FIG. 14 illustrates a state where the inspection target IC package 8 is pressed down from above and accommodated in the accommodation recess 17. In FIGS. 12 to 14, the same components as those of the above-described embodiment are denoted by the same reference numerals.

As illustrated in FIGS. 12 to 14, the socket body 10e according to the fourth modification includes a pin block 11e, the pin plate 13, a guide member 15e, a tapered member 37e, and a pair of springs 391e and 393e as elastic members that bias the tapered member 37e upward.

The tapered member 37e includes a plate-shaped portion 371e that is long along the X-axis direction as a whole. A central portion of the plate-shaped portion 371e in the longitudinal direction has a wide shape. The plate-shaped portion 371e forms a part of a side wall of the accommodation recess 17. The tapered member 37e is supported in a manner of being displaceable in the up-down direction by the two springs 391e and 393e that bias the tapered member 37e upward. In the tapered member 37e, a part of an upper surface of the plate-shaped portion 371e is formed as a tapered surface 375e that is lowered toward the bottom surface of the accommodation recess 17.

One end of each of the springs 391e and 393e is installed inside a wide portion 373e, and the other end of each of the springs 391e and 393e is installed inside the pin block 11e below the wide portion 373e.

When the inspection target IC package 8 is placed in the socket body 10e, the inspection target IC package 8 is guided to an upper side of the accommodation recess 17 by a tapered surface of the guide member 15e and the tapered surface 375e of the tapered member 37e, and is in a state of being elastically supported by the package support portions 20 (the state in FIG. 13).

Thereafter, when the pressure applying mechanism 70 applies a load to the inspection target IC package 8, the inspection target IC package 8 is pressed down, and the spring 201 is contracted to lower support positions of the package support portions 20. Then, the inspection target IC package 8 moves along the tapered surface 375e of the tapered member 37e. Therefore, the inspection target IC package 8 tends to move in the Z-axis negative direction and the Y-axis negative direction along an inclined surface of the tapered surface 375e. However, an end surface (a side surface on a side in the Y-axis negative direction; a right side surface in FIGS. 12 to 14) of the inspection target IC package 8 on a side opposite to a side in contact with the tapered surface 375e abuts against the guide member 15e, and cannot be moved further in the Y-axis negative direction. Therefore, the position of the inspection target IC package 8 in the left-right direction (XY plane) is in a fixed state, and thereafter, the inspection target IC package 8 only changes in position in the Z-axis negative direction.

When the inspection target IC package 8 is further pressed down, the tip end (terminal-side plunger) of each contact probe 40 exposed from the exposed surface 19 starts to come into contact with the corresponding electrode terminal 81. The contact probes 40 can extend and contract in an axial direction (longitudinal direction). Therefore, when the inspection target IC package 8 is pressed down and the electrode terminals 81 are pressed against the contact probes 40, the contact probes 40 in contact therewith start to contract. However, each of the contact probes 40 is disposed so as to be inclined relative to a direction (Z-axis direction) perpendicular to the exposed surface 19. The position of the inspection target IC package 8 in the left-right direction (XY plane) is in a fixed state. Therefore, the contact position where a tip end of the contact probe 40 is in contact with the electrode terminal 81 of the inspection target IC package 8 gradually changes in accordance with the descent of the inspection target IC package 8 (a positional change in the Z-axis negative direction), and the scrubbing operation on a surface of the terminal is performed.

Therefore, also in the fourth modification, similar to the above-described embodiment and the like, the inspection target IC package 8 can be suppressed from moving in the inclination direction when the contact probe 40 and the electrode terminal 81 are brought into contact with each other, and the scrubbing operation can be performed stably.

### Fifth Modification

In the above-described embodiment and modifications, the configuration in which the inspection target IC package is pressed in one direction has been exemplified. In contrast, the inspection target IC package may be pressed in a plurality of directions depending on the inclination direction of the contact probes.

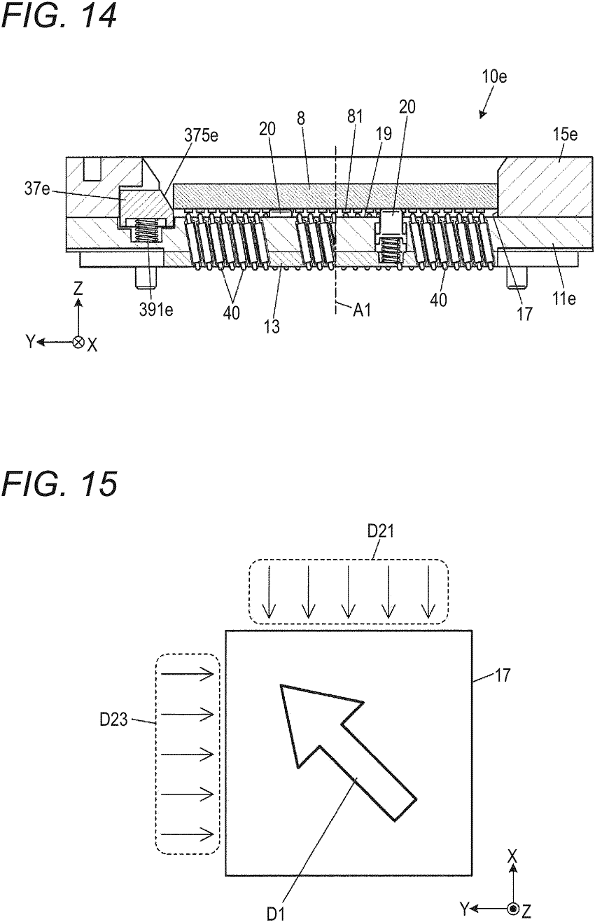

FIG. 15 is a schematic view illustrating a relation between an inclination direction of the contact probes supported by a bottom portion of the accommodation recess 17 and a pressing direction of the inspection target IC package. FIG. 15 is a top view of the accommodation recess 17 as in FIGS. 2, 6, 8, and 12. The X-axis direction, the Y-axis direction, and the Z-axis direction are the same as the directions illustrated in the other drawings. In FIGS. 2, 6, 8, and 12, the inclination direction of the contact probe is a leftward direction (Y-axis positive direction) in the drawing, but in the fifth modification, as illustrated by an arrow D1, the inclination direction is a diagonally upward left direction (X-axis positive direction and Y-axis positive direction) in FIG. 15. Therefore, in the fifth modification, the inspection target IC package is pressed in a direction D21 (X-axis negative direction) and a direction D23 (Y-axis negative direction) that are directions including direction components opposite to the inclination direction D1. Specifically, any of the pressing portions 30, 30c, and 30d illustrated in the above-described embodiment and the first to third modifications are installed on the X-axis positive direction side and the Y-axis positive direction side. The types of the pressing portions installed on the X-axis positive direction side and the Y-axis positive direction side may be different from each other. The inspection target IC package 8 is pressed in the direction D21 (X-axis negative direction) and in the direction D23 (Y-axis negative direction). Alternatively, the tapered member 37e and the springs 391e and 393e in the fourth modification may be installed on the X-axis positive direction side and the Y-axis positive direction side, and the inspection target IC package may be pressed in the directions D21 and D23.

Several embodiments and modifications thereof have been described. These disclosures can be summarized as follows.

According to an aspect of the present disclosure, there is provided an inspection socket including: a pin block that is configured to support a contact probe in a manner of exposing a tip end of the contact probe from an exposed surface and inclining the contact probe in a predetermined direction relative to a direction perpendicular to the exposed surface; and a pressing portion that is configured to press an inspection target IC package that is to come into contact with the contact probe.

According to the aspect of the present disclosure, the pin block can support the contact probe in a manner of inclining the contact probe in the predetermined direction. In addition, the inspection target IC package can be pressed by the pressing portion. The pin block is inclined in the predetermined direction, and therefore, when the contact probe and the electrode terminal of the inspection target IC package are brought into contact with each other, the inspection target IC package is moved based on an inclination direction of the contact probe, and there is a possibility that the scrubbing operation hardly occurs. However, since the inspection target IC package is pressed by the pressing portion, such a situation can be suppressed, and the scrubbing operation can be stably performed when the contact probe and the electrode terminal of the inspection target IC package are brought into contact with each other. In addition, since the inclination directions of the contact probes may be the same, it is not necessary to increase the size of the pin block, and it is not necessary to perform complicated processing on the pin block for supporting the contact probes. Since the inspection target IC package is pressed by the pressing portion, a positioning accuracy of the inspection target IC package can be improved as compared with the case where the pressing portion is not provided.

The pressing portion may be configured to press the inspection target IC package in a pressing direction including a direction component opposite to the predetermined direction.

Even if a force is applied to the inspection target IC package based on the inclination direction of the contact probe when the contact probe and the electrode terminal of the inspection target IC package are brought into contact with each other, the scrubbing operation can be stably performed against the force.

The pressing direction may be a direction parallel to a plate surface of the inspection target IC package.

When the contact probe and the electrode terminal of the inspection target IC package are brought into contact with each other, the inspection target IC package is pressed in a direction perpendicular to the plate surface of the inspection target IC package. Since the pressing direction is a direction parallel to the plate surface of the inspection target IC package, a pressure applying direction and the pressing direction can be different from each other. Therefore, as compared with the case where the pressure applying direction is parallel to the pressing direction, the inspection target IC package itself is less likely to be damaged.

The pressing portion may include a pressing member and an elastic member that is configured to bias the pressing member.

The use of the elastic member facilitates replacement of the inspection target IC package.

The pressing member may include a roller portion.

The inspection target IC package can be pressed by the roller portion, and the inspection target IC package can be suppressed from being damaged.

A biasing direction of the elastic member and the pressing direction may be parallel to each other.

Since the biasing direction of the elastic member that biases the pressing member and the pressing direction are parallel to each other, a mechanism of the pressing portion can be easily designed.

The inspection socket may further include an interposed portion, and the pressing portion may be configured to press the inspection target IC package through the interposed portion.

Since the inspection target IC package can be pressed through the interposed portion, the pressing portion does not directly press the inspection target IC package, and the inspection target IC package can be suppressed from being damaged.

The interposed portion may have a tapered surface.

When the contact probe and the electrode terminal of the inspection target IC package are brought into contact with each other, the inspection target IC package can be moved along the tapered surface, so that the inspection target IC package can be easily replaced.

### REFERENCE SIGNS LIST

1 Inspection socket
10, 10b, 10c, 10d, 10e Socket body
11 Pin block
111 Block-side through hole
113 Groove portion
13 Pin Plate
131 Plate-side through hole
15 Guide member
17 Accommodation recess
19 Exposed surface
20 Package support portion
30, 30c, 30d Pressing portion
31 Pressing member
311 Roller portion
313 Support shaft
317d Swing body
32c Tapered member
33 Elastic member
331, 333, 335c, 337c, 339d Spring
35, 37e Tapered member
391e, 393e Spring
40 Contact probe
50 Lid body
70 Pressure applying mechanism
8 Inspection target IC package
81 Electrode terminal
9 Inspection device
B1 Pressing direction

1. An inspection socket, comprising:
a pin block that is configured to support a contact probe in a manner of exposing a tip end of the contact probe from an exposed surface and inclining the contact probe in a predetermined direction relative to a direction perpendicular to the exposed surface; and
a pressing portion that is configured to press an inspection target IC package that is to come into contact with the contact probe.

2. The inspection socket according to claim 1,
wherein the pressing portion is configured to press the inspection target IC package in a pressing direction including a direction component opposite to the predetermined direction.

3. The inspection socket according to claim 2,
wherein the pressing direction is a direction parallel to a plate surface of the inspection target IC package.

4. The inspection socket according to claim 2,
wherein the pressing portion includes
a pressing member, and
an elastic member that is configured to bias the pressing member.

5. The inspection socket according to claim 4,
wherein the pressing member includes a roller portion.

6. The inspection socket according to claim 4,
wherein a biasing direction of the elastic member and the pressing direction are parallel to each other.

7. The inspection socket according to claim 1, further comprising an interposed portion,
wherein the pressing portion is configured to press the inspection target IC package through the interposed portion.

8. The inspection socket according to claim 7,
wherein the interposed portion has a tapered surface.

9. The inspection socket according to claim 5,
wherein a biasing direction of the elastic member and the pressing direction are parallel to each other.

10. The inspection socket according to claim 2, further comprising an interposed portion,
wherein the pressing portion is configured to press the inspection target IC package through the interposed portion.

11. The inspection socket according to claim 3, further comprising an interposed portion,
wherein the pressing portion is configured to press the inspection target IC package through the interposed portion.

12. The inspection socket according to claim 4, further comprising an interposed portion,
wherein the pressing portion is configured to press the inspection target IC package through the interposed portion.

13. The inspection socket according to claim 5, further comprising an interposed portion,
wherein the pressing portion is configured to press the inspection target IC package through the interposed portion.

14. The inspection socket according to claim 6, further comprising an interposed portion,
wherein the pressing portion is configured to press the inspection target IC package through the interposed portion.

15. The inspection socket according to claim 8, further comprising an interposed portion,
wherein the pressing portion is configured to press the inspection target IC package through the interposed portion.

16. The inspection socket according to claim 9, further comprising an interposed portion,
wherein the pressing portion is configured to press the inspection target IC package through the interposed portion.
